(19) United States
(12) Patent Application Publication
(10) Pub. No.: US 2022/0302680 A1
(43) Pub. Date: Sep. 22, 2022

(54) BEAM SHAPING METASURFACE

(71) Applicant: Facebook Technologies, LLC, Menlo Park, CA (US)

(72) Inventors: Maik Andre Scheller, Redmond, WA (US); Liliana Ruiz Diaz, Redmond, WA (US); Hao Yang, Los Angeles, CA (US)

(21) Appl. No.: 17/207,142

(22) Filed: Mar. 19, 2021

(51) Int. Cl. H01S 5/183; G02B 27/01

(52) U.S. Cl. CPC H01S 5/18388; H01S 5/18361; H01S 5/18322; G02B 27/0172; G02B 2027/0178

(57) ABSTRACT

A laser such as a vertical-cavity surface-emitting laser (VCSEL) emits laser light. A beam shaping metasurface is configured to apply a beam shaping profile to the laser light to generate shaped laser light in response to receiving the laser light.

### TECHNICAL FIELD

This disclosure relates generally to optics, and in particular to beam shaping optics including metasurfaces.

### BACKGROUND INFORMATION

Refractive lenses are commonly used to focus light emitting from a light source. For example, refractive lenses may have convex or concave surfaces to focus or defocus a beam of light emitted from the light source. However, refractive lenses may have significant thickness, footprint, and/or weight with respect to the light sources, especially to achieve certain beam shaping functionality. Furthermore, the refractive lenses typically require an additional process step of bonding (and aligning) the refractive lens to the light source.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 illustrates a vertical-cavity surface-emitting laser (VCSEL) as an example light source having a beam shaping metasurface, in accordance with aspects of the disclosure.

FIGS. 2A-2D illustrate an example implementation of a hybrid beam shaping metasurface, in accordance with aspects of the disclosure.

FIG. 3 illustrates a process of fabricating a light source having a metasurface, in accordance with aspects of the disclosure.

FIGS. 4A-4K illustrates various VCSEL structures for fabricating metasurfaces, in accordance with aspects of the disclosure.

FIGS. 5A-5B illustrate an example focusing beam shaping profile that controls a beam divergence of incident laser light, in accordance with aspects of the disclosure.

FIGS. 6A-6B illustrate an example defocusing beam shaping profile that controls a beam divergence of incident laser light, in accordance with aspects of the disclosure.

FIGS. 7A-7B illustrate an example beam shaping profile that controls a deflection angle of incident laser light, in accordance with aspects of the disclosure.

FIG. 8A illustrates an example beam shaping profile that includes a meta-lens component to control a beam divergence of laser light and meta-prism components that controls a deflection angle of laser light, in accordance with aspects of the disclosure.

FIG. 8B illustrates another example beam shaping profile that includes a meta-lens component to control a beam divergence of laser light and a meta-prism component that controls a deflection angle of laser light, in accordance with aspects of the disclosure.

FIGS. 9A-9C illustrate an example head mounted device that includes a near-eye optical element having light sources that include beam shaping metasurfaces, in accordance with aspects of the disclosure.

### DETAILED DESCRIPTION

Embodiments of beam shaping metasurfaces are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In some implementations of the disclosure, the term “near-eye” may be defined as including an element that is configured to be placed within 50 mm of an eye of a user while a near-eye device is being utilized. Therefore, a “near-eye optical element” or a “near-eye system” would include one or more elements configured to be placed within 50 mm of the eye of the user.

In aspects of this disclosure, visible light may be defined as having a wavelength range of approximately 380 nm- 700 nm. Non-visible light may be defined as light having wavelengths that are outside the visible light range, such as ultraviolet light and infrared light. Infrared light having a wavelength range of approximately 700 nm−1 mm includes near-infrared light. In aspects of this disclosure, near-infrared light may be defined as having a wavelength range of approximately 700 nm−1.4 μm.

In aspects of this disclosure, the term “transparent” may be defined as having greater than 90% transmission of light. In some aspects, the term “transparent” may be defined as a material having greater than 90% transmission of visible light.

Embodiments of the disclosure include beam shaping metasurfaces that may be placed over a light source to apply a beam shaping profile to generate shaped light. The beam shaping metasurfaces may be placed over the aperture of lasers including vertical-cavity surface-emitting lasers (VCSELs), for example. In particular implementations, the beam shaping metasurface is formed of a refractive semiconductor layer or a refractive dielectric layer that may be integrated into the light source. Using a refractive semiconductor layer or a refractive dielectric layer may allow the metasurfaces to be fabricated in the same process that the light source is fabricated. In a particular example, VCSELs are formed on a wafer and the beam shaping metasurfaces are formed over apertures of the VCSELs while the VCSELs are still on the wafer (before the wafer is diced into individual VCSELs). In some implementations, the beam shaping metasurface includes a first refractive semiconductor layer and a second refractive semiconductor layer.

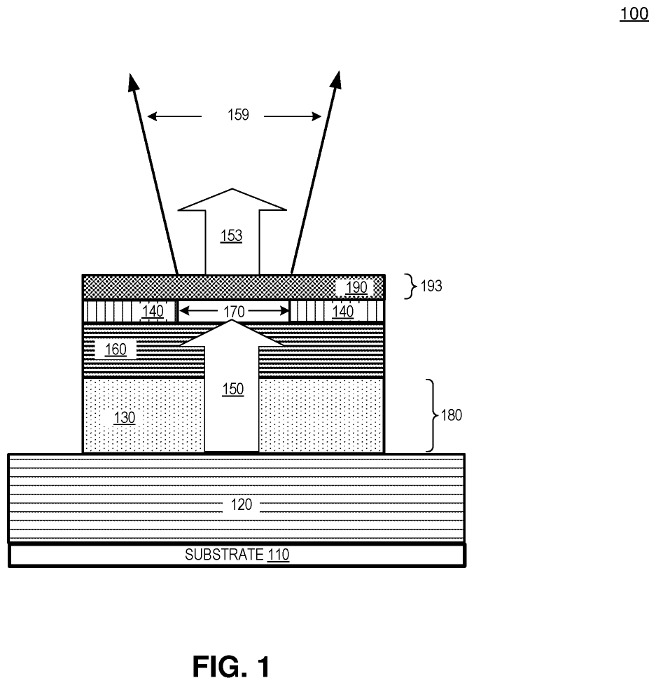

The beam shaping metasurface may be configured to control a beam divergence of the shaped light and/or a deflection angle of the shaped light. In an example context, the beam shaping metasurfaces are included in near-infrared VCSELs that are in a near-eye optical element of a head mounted device. The near-infrared VCSELs illuminate an eyebox area to facilitate imaging of the eyebox (for eye-tracking purposes, for example). The implementations of this disclosure may reduce weight, footprint, and/or thickness of a light source that includes a beam shaping element. Furthermore, the cost to fabricate a beam shaping light source may be reduced. Additionally, in examples where the beam shaping metasurface is fabricated in semiconductor layers or dielectric layers, the yield and/or precision of beam shaping light sources may be increased as a result of the tolerances of modern semiconductor processes. These and other embodiments are described in more detail in connection with FIGS. 1-9C.

FIG. 1 illustrates a vertical-cavity surface-emitting laser (VCSEL) 100 as an example light source having a beam shaping metasurface 190, in accordance with aspects of the disclosure. VCSEL 100 includes a semiconductor substrate 110, a first reflector layer 120, an active region 130, an aperture definition layer 140 defining aperture 170, and a second reflector layer 160. First reflector layer 120 may be configured as an N doped Distributed Bragg Reflector (DBR) and second reflector layer 160 may be configured as a P doped DBR, in some implementations. Aperture definition layer 140 may be a metal layer, in some implementations. Beam shaping metasurface 190 may have a thickness 193 of less than 500 nm, in some aspects. Beam shaping metasurface 190 may be formed in a refractive semiconductor layer. The refractive semiconductor layer may have a high refractive index. In some aspects, the refractive semiconductor layer has a refractive index greater than three. In a particular example, metasurface 190 includes a gallium arsenide (GaAs) layer. Metasurface 190 may include an aluminum-gallium-arsenide (AlGaAs) layer. Metasurface 190 may include a transparent dielectric material such as silicon-dioxide (SiO₂), aluminum-oxide (Al₂O₃), silicon-nitride (SiN), titanium-dioxide (TiO₂) and/or other suitable transparent dielectric material.

In operation, laser light 150 is generated in laser cavity 180 of VCSEL 100 when VCSEL 100 receives electrical current. While not specifically illustrated, a first electrical contact connected to first reflector layer 120 and a second electrical contact connected to second reflector layer 160 allow for a voltage potential across first reflector layer 120 and second reflector layer 160 when VCSEL 100 is powered on. Laser cavity 180 is disposed between first reflector layer 120 and second reflector layer 160. First reflector layer 120 may be approximately 99.9% reflective and second reflector layer 160 may be approximately 99.0% reflective, for example. While laser light reflects between first reflector layer 120 and second reflector layer 160 in laser cavity 180, a portion of the laser light 150 propagates through second reflector layer 160 and through aperture 170 and becomes incident on beam shaping metasurface 190. Beam shaping metasurface 190 receives laser light 150 and generates shaped laser light 153 in response to receiving laser light 150 from laser cavity 180. In the illustration of FIG. 1, beam shaping metasurface 190 is configured to defocus the laser light 150 so that shaped laser light 153 has a diverging beam shape 159. In other aspects of the disclosure, beam shaping metasurfaces may be configured to generate converging beam shapes, collimated beam shapes, and/or deflected beam shapes.

The line width of VCSEL 100 may be very narrow (e.g. 2-4 nm). VCSEL 100 may emit collimated laser light 150 prior to laser light 150 being shaped by metasurface 190 into shaped laser light 153. VCSEL 100 may be a visible light VCSEL emitting laser light 150 having a wavelength centered around a wavelength in the visible spectrum (e.g. 550 nm for green light). VCSEL 100 may be a near-infrared VCSEL emitting laser light 150 having a wavelength centered around 850 nm. VCSEL 100 may be a near-infrared VCSEL emitting laser light 150 having a wavelength centered around 940 nm. VCSEL 100 may be an ultraviolet VCSEL emitting laser light 150 having a wavelength centered around 350 nm.

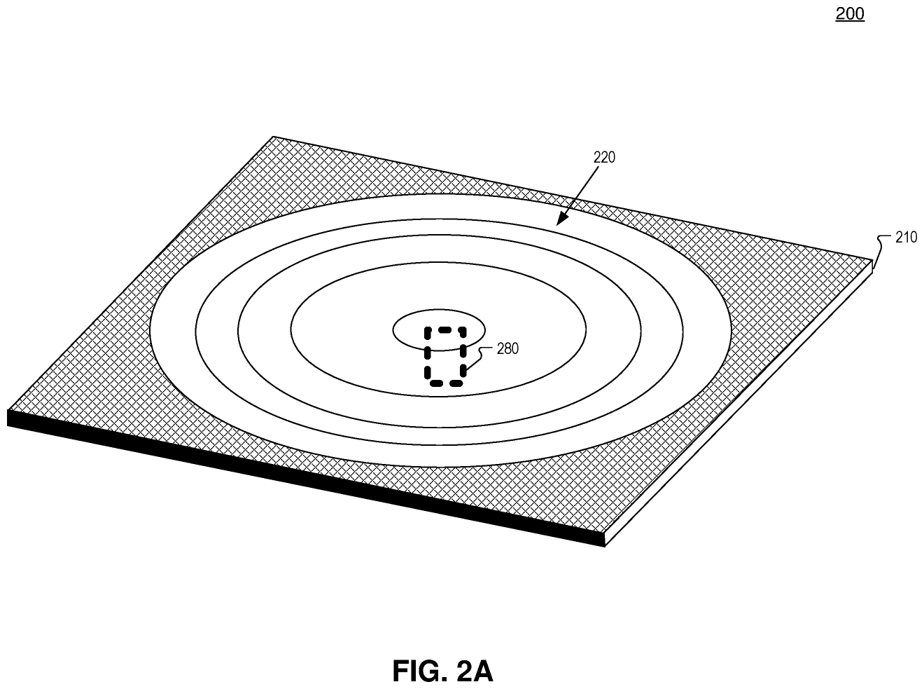

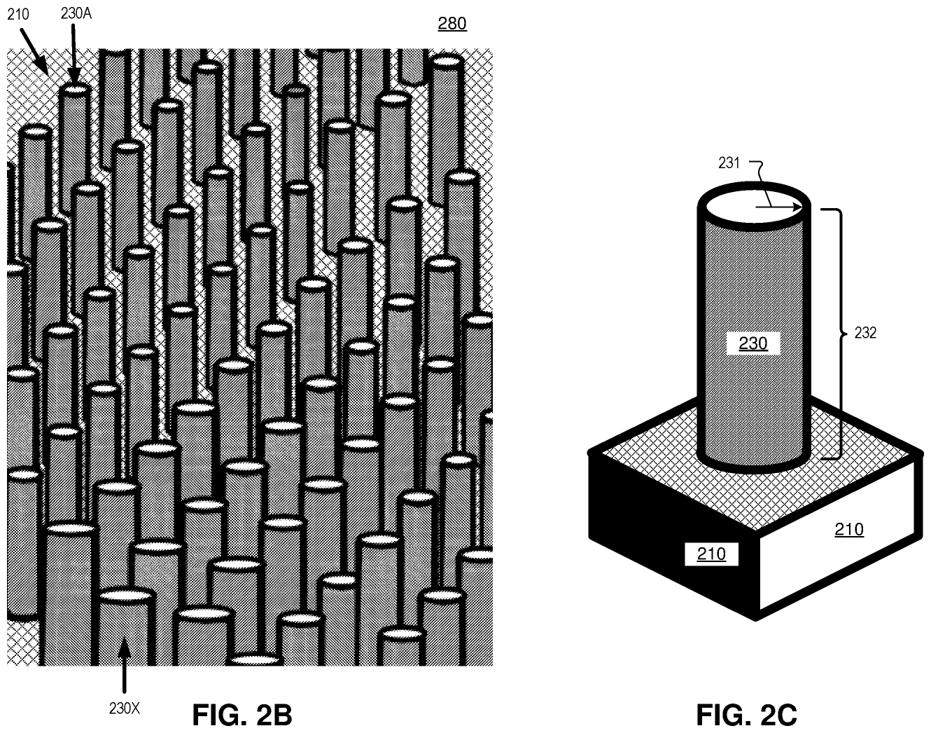

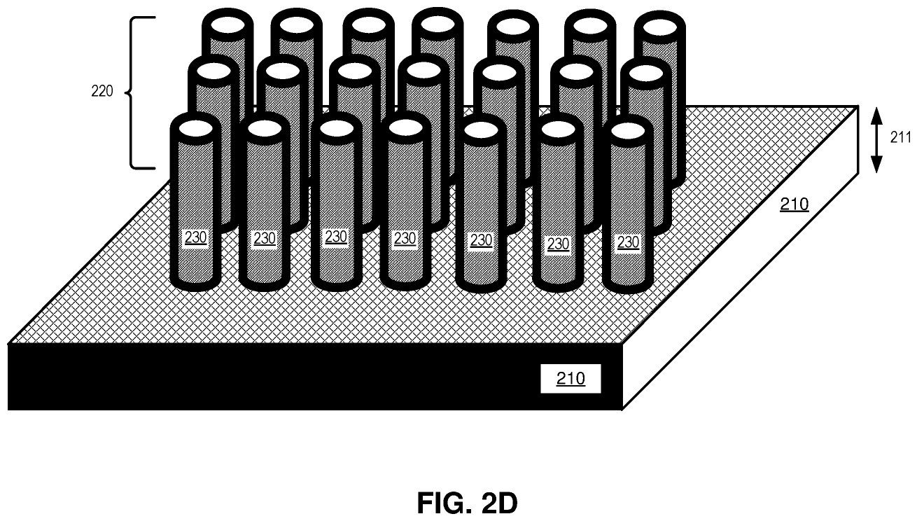

FIGS. 2A-2D illustrate an example implementation of a hybrid beam shaping metasurface, in accordance with aspects of the disclosure. FIG. 2A illustrates an example hybrid beam shaping metasurface 200 that includes a first refractive semiconductor layer 210 and a second refractive semiconductor layer 220. In some implementations, layer 210 and 220 may include transparent dielectric materials instead of semiconductor materials. Metasurface 200 may be used as an example of metasurface 190, in FIG. 1. Metasurface 200 may be polarization insensitive such that it can shape laser light 150 into shaped laser light 153 regardless of the polarization orientation of incident laser light 150.

FIG. 2B illustrates a zoomed-in view of section 280 of metasurface 200 of FIG. 2A. FIG. 2B illustrates that a plurality of nanostructures 230 are formed in the second refractive semiconductor layer 220 and are disposed on the first refractive semiconductor layer 210. In the particular illustration, nanostructures 230 are shaped as nanopillars that may have different radii and are arranged in two-dimensions. FIG. 2C illustrates that a nanostructure 230 that is a nanopillar having a radius 231 and a height 232 where the nanostructure is disposed over first refractive semiconductor layer 210. In other implementations, a nanostructure 230 that is different than a nanopillar may be used as the meta-unit in metasurface 200. FIG. 2B illustrates that the nanopillar that is nanostructure 230A may have a smaller radius than the nanopillar that is nanostructure 230X. Metasurface 200 may include a plurality of nanopillars having a first radius and second nanopillars having a second radius that is different from the first radius. The radius of nanopillars may progressively increase or decrease, in some implementations.

Metasurface 200 has meta-units or nanostructures that have sub-wavelength dimensions. In contrast, diffractive optical structures (e.g. Bragg gratings or holograms) have diffractive structures that are sized at or above the wavelength of the light the diffractive structure is tuned to act on. By way of example, if VCSEL 100 emits laser light centered around 850 nm, nanostructures 230 in metasurface 200 are dimensioned such that the longest dimension is less than 850 nm.

FIG. 2D illustrates that first refractive semiconductor layer 210 may have a constant thickness 211, while second refractive semiconductor layer 220 has varied thickness due to nanostructures 230 providing varying depth to second refractive semiconductor layer 220 to alter the phase of incident laser light 150 to provide the intended beam shaping profile. First refractive semiconductor layer 210 may have a first refractive index that is lower than a second refractive index of second refractive semiconductor layer 220 to increase the index contrast. The first refractive index and the second refractive index may be higher than three for near-infrared wavelengths.

In an implementation, first refractive semiconductor layer 210 includes indium-gallium-phosphate (Ga_{0.5}In_{0.5}P). Second refractive semiconductor layer 220 may include gallium-arsenide (GaAs). Second refractive semiconductor layer 220 may include aluminum-gallium-arsenide (AlGaAs).

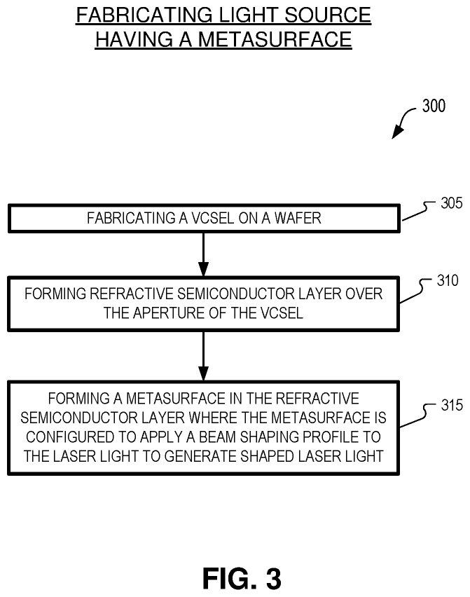

FIG. 3 illustrates a process of fabricating a light source having a metasurface, in accordance with aspects of the disclosure. The order in which some or all of the process blocks appear in process 300 should not be deemed limiting. Rather, one of ordinary skill in the art having the benefit of the present disclosure will understand that some of the process blocks may be executed in a variety of orders not illustrated, or even in parallel.

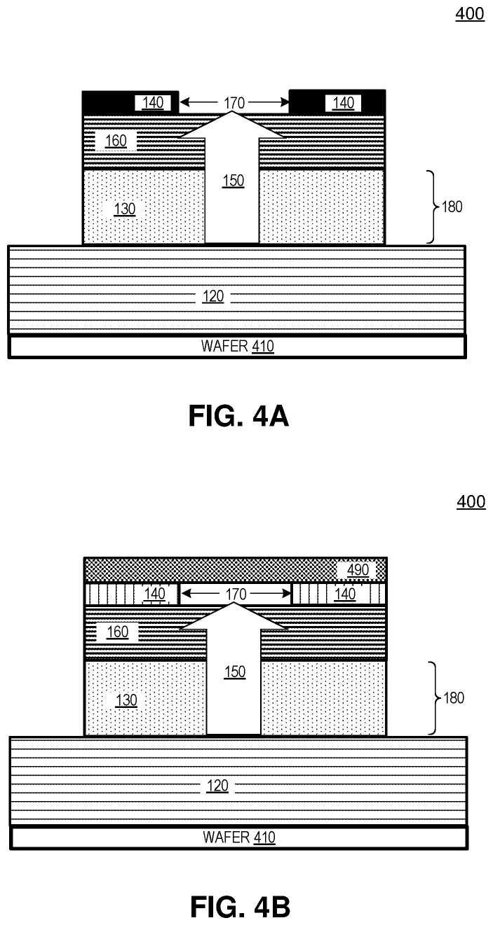

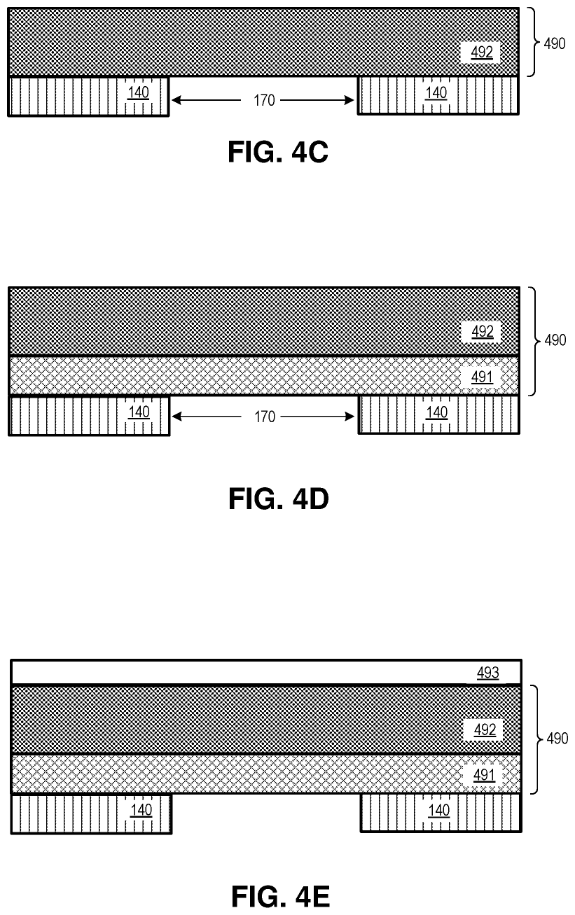

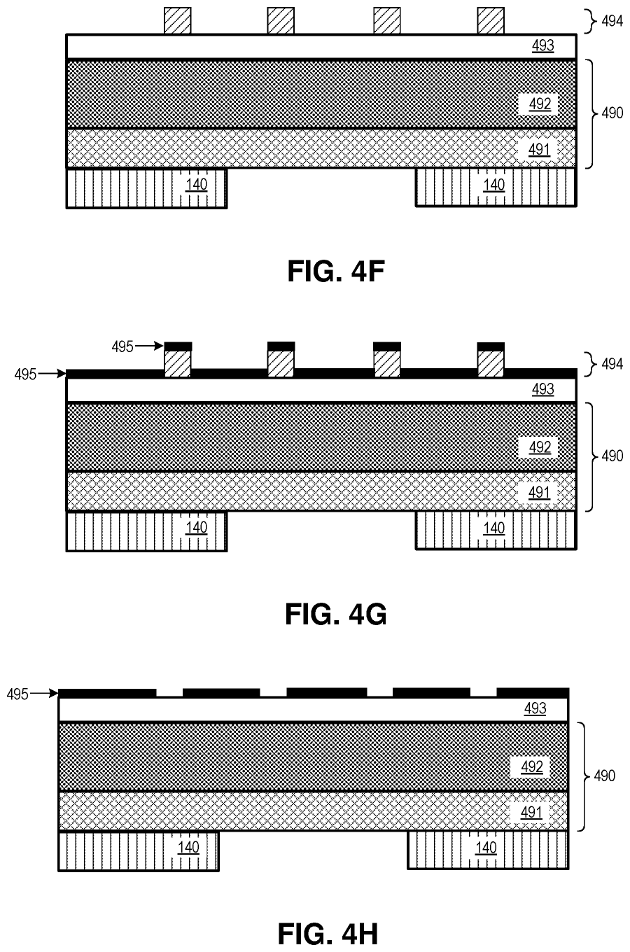

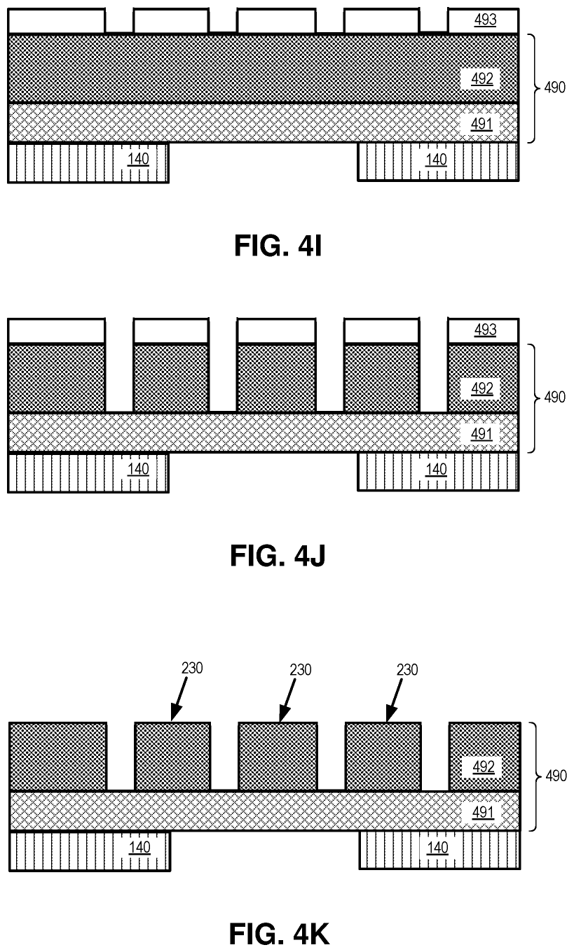

In process block 305, a VCSEL is fabricated on a wafer. The VCSEL is configured to emit laser light through an aperture of the VCSEL. FIG. 4A illustrates a VCSEL structure 400 fabricated on a wafer 410, for example. First reflector layer 120 may be grown on a semiconductor substrate included in wafer 410, for example. While not specifically illustrated, those skilled in the art appreciate that a wafer may include hundreds or thousands of VCSEL structures 400 where the VCSEL structures 400 are all fabricated on the same wafer and later the wafer is diced into individual VCSELs.

In process block 310, a refractive semiconductor layer is formed over the aperture of the VCSEL while the VCSEL remains on the wafer. The refractive semiconductor layer may include gallium-arsenide and/or aluminum-gallium-arsenide. FIG. 4B illustrates a refractive semiconductor layer 490 formed over aperture 170, for example. The refractive semiconductor layer 490 may be formed over the aperture of the VCSEL using a Molecular-beam epitaxy (MBE) or Metalorganic vapour-phase epitaxy (MOVPE). technique, in some implementations. In some implementations, a dielectric material such as silicon-dioxide (SiO₂), aluminum-oxide (A1₂O₃), silicon-nitride (SiN), or other transparent dielectric material is formed over the aperture of the VCSEL instead of a refractive semiconductor layer. The metasurface is then formed of the transparent dielectric material. The transparent dielectric material may be deposited over the aperture of the VCSEL by Chemical Vapor Deposition (CVD), magnetron sputtering or wafer bonding the dielectric wafer (thickness of 100 um to 2 mm typically) to the VCSEL. FIG. 4C illustrates a first implementation where a single refractive semiconductor layer 492 makes up the entirety of refractive semiconductor layer 490. FIG. 4D illustrates a second example implementation where a refractive layer 491 is formed prior to forming refractive semiconductor layer 492. Refractive layer 491 is disposed between the VCSEL and refractive semiconductor layer 492. Refractive layer 491 may be a refractive semiconductor layer (e.g. indium-gallium-phosphate), in some implementations.

In process block 315, a metasurface is formed in the refractive semiconductor layer. The metasurface is formed in a subtractive process (e.g. etching) of the refractive semiconductor layer. The metasurface is configured to apply a beam shaping profile to laser light (e.g. laser light 150) to generate shaped laser light (e.g. shaped laser light 153).

In an implementation of process 300, the subtractive process includes etching nanostructures of the metasurface into the refractive semiconductor layer (e.g. refractive semiconductor layer 492).

FIGS. 4E-4K illustrate process examples for fabricating a light source (e.g. a VCSEL) that includes a beam shaping metasurface formed in an etching process, in accordance with aspects of the disclosure. FIGS. 4E-4K illustrate an etching process in an implementation where refractive semiconductor layer 490 includes refractive semiconductor layer 492 and refractive layer 491, although those skilled in the art appreciate that the illustrated process could be applied to the implementation of FIG. 4C where a single refractive semiconductor layer 492 makes up the entirety of refractive semiconductor layer 490.

FIG. 4E illustrates a silicon-dioxide (SiO₂) layer 493 being formed on refractive semiconductor layer 492.

FIG. 4F illustrates a patterned photoresist 494 formed in a photolithography process.

In FIG. 4G, a Chromium layer 495 is formed over photoresist 494 and silicon-dioxide layer 493.

FIG. 4H illustrates a liftoff process where photoresist 494 (and the portion of chromium layer 495 covering photoresist 494) are removed to leave a patterned chromium layer 495.

FIG. 4I illustrates a first etching process to form a patterned silicon-dioxide layer 493 that will define the nanostructures of the metasurface. The first etching process may include an inductively coupled plasma etching process or wet etching.

FIG. 4J illustrates a second etching process to etch the refractive semiconductor layer 492 into nanostructures of the metasurface. The second etching process may include a reactive ion etching (ME) dry-etch process. In some implementations, refractive layer 491 (e.g. indium-gallium-phosphate) may function as an etch stop layer for the RIE dry-etch process.

FIG. 4K illustrates a removal of the patterned silicon-dioxide layer 493 to leave the nanostructures 230 formed in the refractive semiconductor layer 492. Patterned silicon-dioxide layer 493 may be removed from refractive semiconductor layer 492 using a rinse technique known by those skilled in the art.

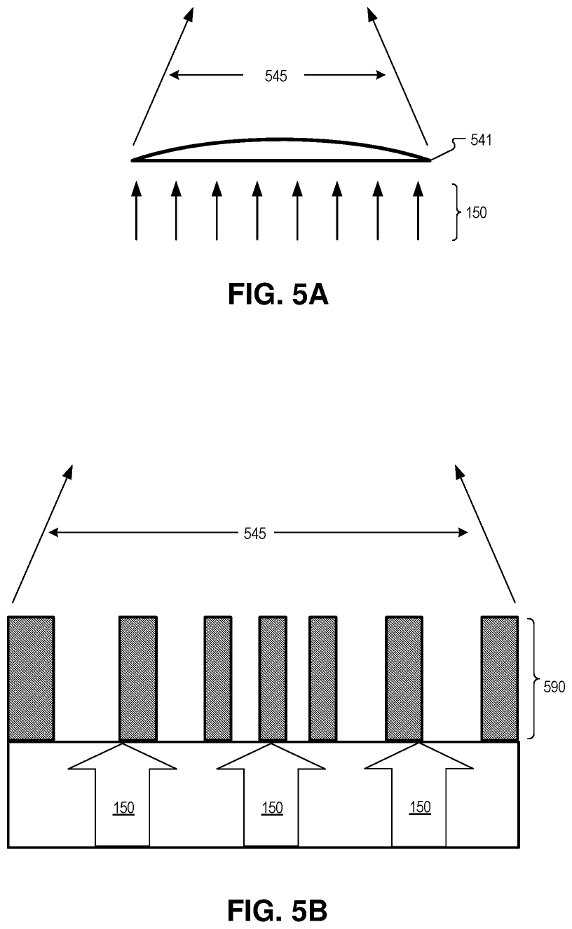

FIGS. 5A-5B illustrate an example beam shaping profile 541 that controls a beam divergence of incident laser light 150, in accordance with aspects of the disclosure. Beam shaping profile 541 controls a beam divergence of incident laser light 150 by focusing laser light 150 into shaped laser light 545. Shaped laser light 545 is converging. Beam shaping profile 541 may be considered a meta-lens. FIG. 5B illustrates beam shaping metasurface 590 can be configured similarly to beam shaping profile 541 to control the beam divergence of incident laser light 150 to generate shaped laser light 545. Beam shaping metasurface 590 may be configured to have different focal lengths. Beam shaping metasurface 590 may also be configured to collimate laser light 150 to generate collimated shaped laser light 545.

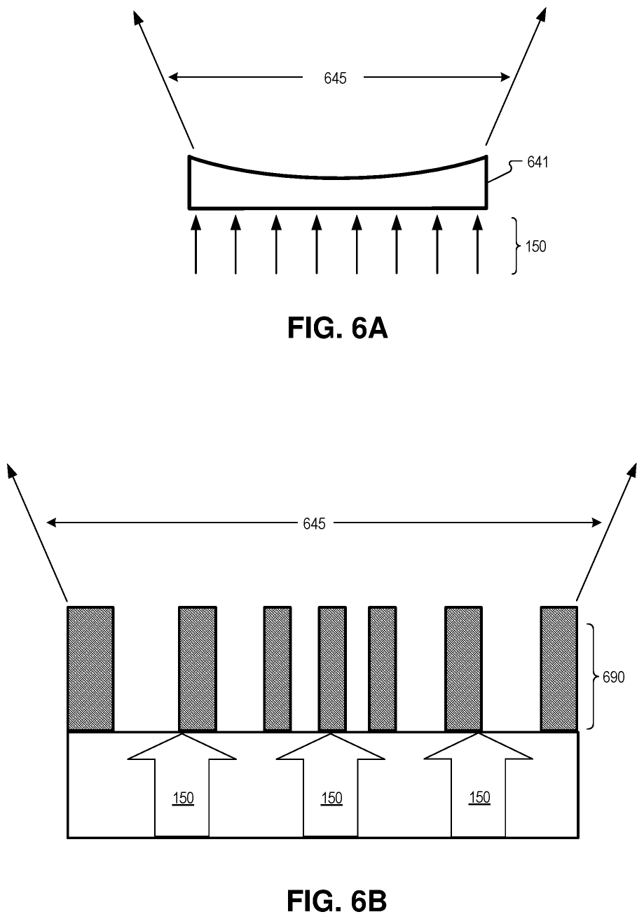

FIGS. 6A-6B illustrate an example beam shaping profile 641 that controls a beam divergence of incident laser light 150, in accordance with aspects of the disclosure. Beam shaping profile 641 controls a beam divergence of incident laser light 150 by defocusing laser light 150 into shaped laser light 645. Shaped laser light 645 is diverging. Beam shaping profile 641 may be considered a meta-lens. FIG. 6B illustrates beam shaping metasurface 690 can be configured similarly to beam shaping profile 641 to control the beam divergence of incident laser light 150 to generate shaped laser light 645. In some implementations, the beam divergence angle of a diverging shaped laser light 645 may have a divergence angle between 20 degrees and 60 degrees.

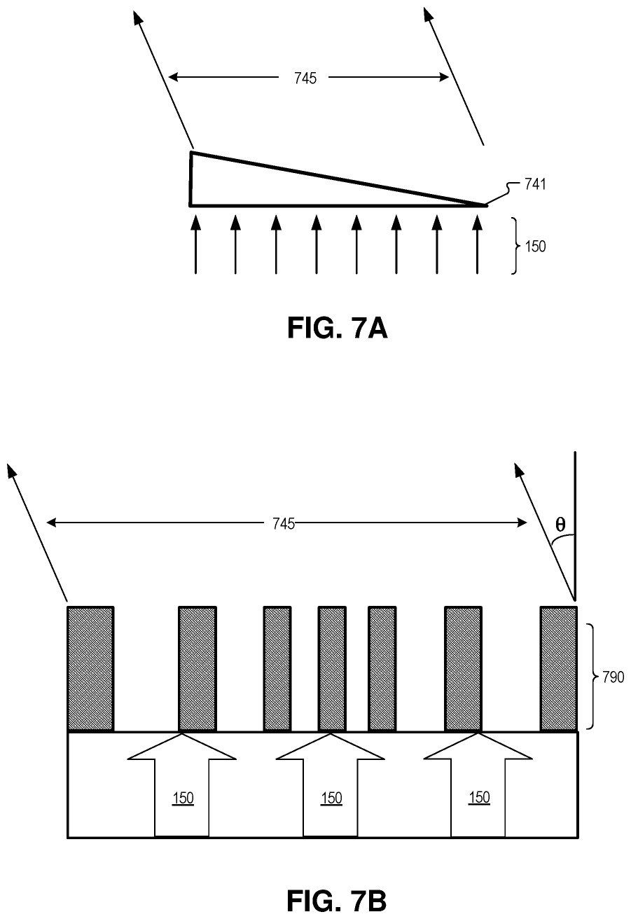

FIGS. 7A-7B illustrate an example beam shaping profile 741 that controls a deflection angle of incident laser light 150, in accordance with aspects of the disclosure. Beam shaping profile 741 controls a deflection angle of incident laser light 150 by deflecting laser light 150 into shaped laser light 745. Beam shaping profile 741 may be considered a meta-prism. FIG. 7B illustrates beam shaping metasurface 790 can be configured similarly to beam shaping profile 741 to control the deflection angle 0 of incident laser light 150 to generate shaped laser light 745. Beam shaping metasurface 790 may be configured to deflect incident laser light 150 at different angles 0 where 0 is measured as the angle between incident laser light 150 and deflected shaped laser light 745.

The deflection angle θ can be designed according to a meta-prism phase profile according to the following relationship:

ϕ(x,y)=2π/λ*x*sin θ Equation (1)

where ϕ represents the phase on the meta-prism surface, θ represents an angle between the incident light and deflected light, λ is the wavelength of laser light, and (x,y) are the spatial coordinates with respect to the center of the meta-prism. The phase change rate on the meta-prism adheres to the following relationship:

dϕ/dx=2π/λ*sin θ Equation (2)

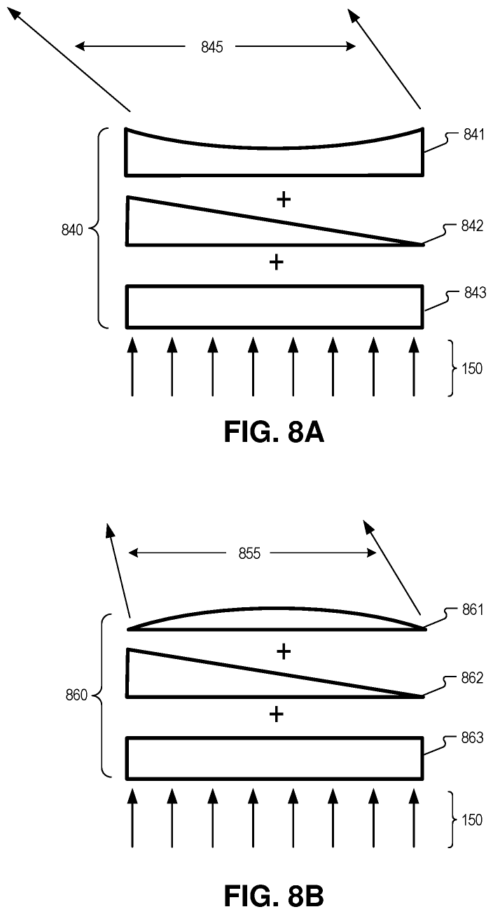

FIG. 8A illustrates an example beam shaping profile 840 that includes a meta-lens component to control a beam divergence of laser light 150 and meta-prism components that controls a deflection angle of laser light 150, in accordance with aspects of the disclosure. Beam shaping profile 840 includes a meta-lens component 841 that defocuses laser light 150. Beam shaping profile 840 also includes meta-prism component 842 and a meta-prism component 843 to control a deflection angle of incident laser light 150 by deflecting laser light 150. Meta-prism component 843 is illustrated as a prism having a slope running into the page. Together, meta-prism component 842 and meta-prism component 843 control the deflection angle of shaped laser light 845 in two dimensions. Beam shaping metasurfaces (e.g. metasurface 190) of this disclosure can be configured similarly to beam shaping profile 840 to control the beam divergence and deflection angle of incident laser light 150 to generate shaped laser light 845.

FIG. 8B illustrates an example beam shaping profile 860 that includes a meta-lens component to control a beam divergence of laser light 150 and meta-prism components that controls a deflection angle of laser light 150, in accordance with aspects of the disclosure. Beam shaping profile 860 includes a meta-lens component 861 that focuses laser light 150. Beam shaping profile 860 also includes meta-prism component 862 and a meta-prism component 863 to control a deflection angle of incident laser light 150 by deflecting laser light 150. Meta-prism component 863 is illustrated as a prism having a slope running into the page. Together, meta-prism component 862 and meta-prism component 863 control the deflection angle of shaped laser light 855 in two dimensions. Beam shaping metasurfaces (e.g. metasurface 190) of this disclosure can be configured similarly to beam shaping profile 860 to control the beam divergence and deflection angle of incident laser light 150 to generate shaped laser light 855.

FIGS. 8A and 8B illustrate that virtually any beam shaping profile can be written into metasurfaces of this disclosure. Consequently, metasurfaces of the disclosure can be configured to perform any combination of focusing, defocusing, and/or deflecting laser light 150 to generate shaped laser light.

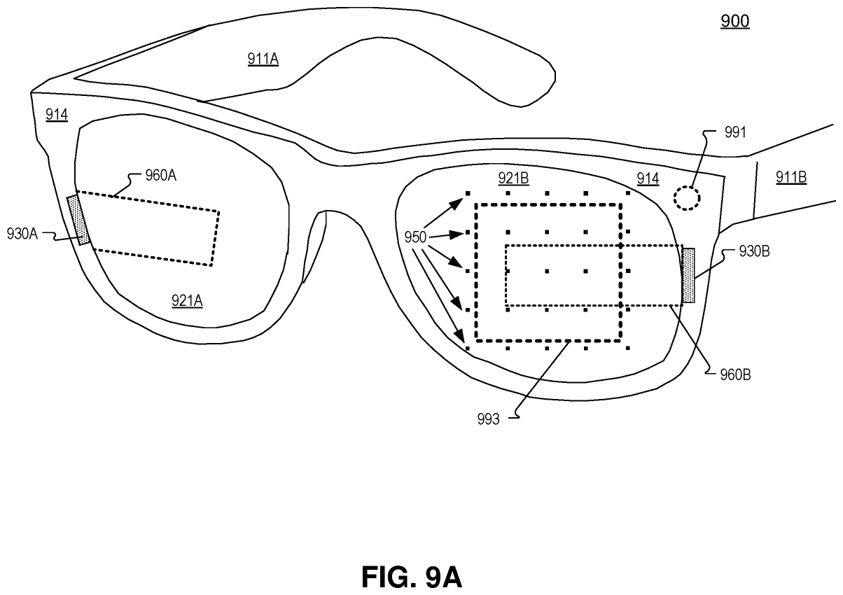

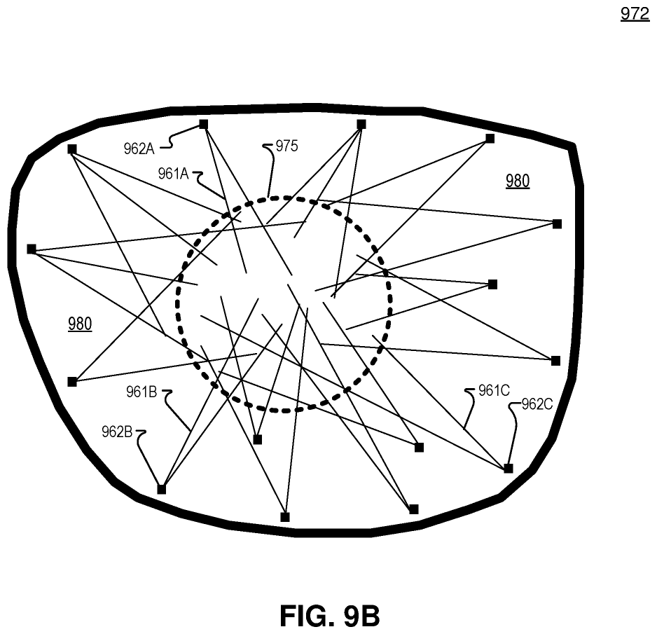

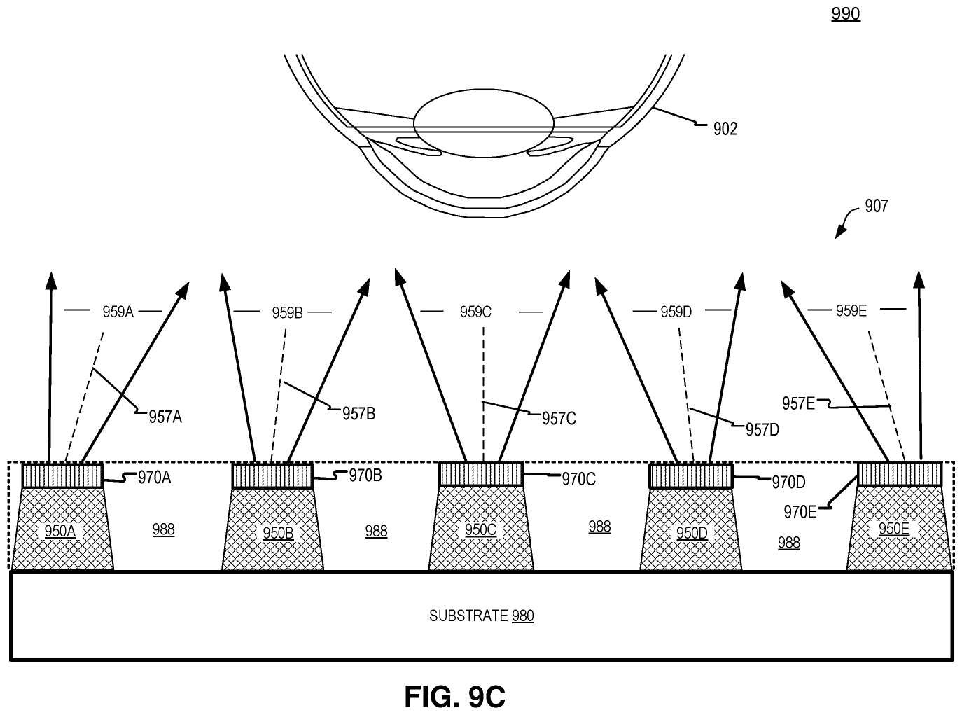

FIG. 9A illustrates an example head mounted device 900 that includes an array of light sources, such as VCSELs, emitting infrared light in an eyebox direction, in accordance with an embodiment of the disclosure. Head mounted device 900 includes frame 914 coupled to arms 911A and 911B. Lenses 921A and 921B are mounted to frame 914. Lenses 921 may be prescription lenses matched to a particular wearer of head mounted device or non-prescription lenses. The illustrated head mounted device 900 is configured to be worn on or about a head of a user of the head mounted device.

In FIG. 9A, head mounted device 900 is a head mounted display (HMD) where each lens 921 includes a waveguide 960 to direct image light generated by a display 930 to an eyebox area for viewing by a wearer of head mounted device 900. Display 930 may include an LCD, an organic light emitting diode (OLED) display, micro-LED display, quantum dot display, pico-projector, or liquid crystal on silicon (LCOS) display for directing image light to a wearer of head mounted device 900. Some head mounted devices may not necessarily be HMDs but still include infrared light sources to illuminate an eyebox region for eye-tracking purposes, for example.

The frame 914 and arms 911 of the head mounted device may include supporting hardware of head mounted device 900. Head mounted device 900 may include any of processing logic, wired and/or wireless data interface for sending and receiving data, graphic processors, and one or more memories for storing data and computer-executable instructions. In one embodiment, head mounted device 900 may be configured to receive wired power. In one embodiment, head mounted device 900 is configured to be powered by one or more batteries. In one embodiment, head mounted device 900 may be configured to receive wired data including video data via a wired communication channel. In one embodiment, head mounted device 900 is configured to receive wireless data including video data via a wireless communication channel.

Lenses 921 may appear transparent to a user to facilitate augmented reality or mixed reality where a user can view scene light from the environment around her while also receiving image light directed to her eye(s) by waveguide(s) 960. Lenses 921 may include an optical combiner 993 for directing reflected infrared light (emitted by light sources 950) to an eye-tracking camera (e.g. camera 991). Those skilled in the art understand that the array of light sources 950 on a transparent substrate could also be included advantageously in a VR headset where the transparent nature of the optical structure allows a user to view a display in the VR headset. In some embodiments of FIG. 9A, image light is only directed into one eye of the wearer of head mounted device 900. In an embodiment, both displays 930A and 930B are included to direct image light into waveguides 960A and 960B, respectively. The term VCSEL is used throughout this disclosure as an example of a light source in general, although those skilled in the art appreciate that in some embodiments, other lasers may be used instead of the specifically described VCSELs.

Lens 921B includes an array of VCSELs 950 arranged in an example 5×5 array. The VCSELs 950 in the array may not be evenly spaced, in some embodiments. VCSELs 950 may be near-infrared light sources directing their emitted near-infrared light in an eyeward direction to an eyebox area of a wearer of head mounted device 900. VCSELs 950 may emit near-infrared light having a wavelength of 850 nm or 940 nm, for example. Very small metal traces or transparent conductive layers (e.g. indium tin oxide) may run through lens 921B to facilitate selective illumination of each VCSEL 950. Lens 921A may be configured similarly to the illustrated lens 921B.

While VCSELs 950 may introduce occlusions into an optical system included in a head mounted device 900, VCSELs 950 and corresponding routing may be so small as to be unnoticeable or optically insignificant to a wearer of a head mounted device. Additionally, any occlusion from VCSELs 950 will be placed so close to the eye as to be unfocusable by the human eye and therefore assist in the VCSELs 950 being not noticeable. In addition to a wearer of head mounted device 900 noticing VCSELs 950, it may be preferable for an outside observer of head mounted device 900 to not notice VCSELs 950.

The beam shaping metasurfaces of this disclosure may be used for beam shaping VCSELs 950 to illuminate an eyebox region with near-infrared light. The beam shaping of the VCSELs 950 may be designed to provide uniform illumination to the eyebox region for imaging purposes by increasing the divergence angle of the VCSELs 950.

FIG. 9B illustrates an example near-eye optical element 972 that includes a plurality of light sources 962 that include a laser (e.g. a VCSEL) and a beam shaping metasurface. Light sources 962 may be coupled with refractive layer 980. Near-eye optical element 972 may be included into head mounted device 900, for example. For purposes of illuminating an eyebox region 975, it may be advantageous to expand and tilt the narrow cone of laser light (e.g. laser light 150) to illuminate the eyebox region 975. To illuminate eyebox region 975, the light sources 962 may benefit from different metasurfaces having different beam shaping profiles due to the different physical location of the light sources 962 with respect to eyebox region 975. For example, light source 962A may have a first metasurface with a first beam shaping profile configured to generate first shaped laser light 961A, second light source 962B may have a second metasurface with a second beam shaping profile configured to generate second shaped laser light 961B, and light source 962C may have a third metasurface with a third beam shaping profile configured to generate third shaped laser light 961C.

FIG. 9C illustrates a top view of an example near-eye optical element 990 including a plurality of VCSELs 950A-950E and corresponding beam shaping metasurfaces 970A-970E. The plurality of VCSELs 950 are configured to emit narrow-band near infrared light through their emission apertures to an eyeward side 907 of near-eye optical element. Beam shaping metasurfaces 970 are formed over the emission apertures of the plurality of VCSELs and the beam shaping metasurfaces 970 may provide different divergence angles to defocus the narrow-band near-infrared light emitted by the VCSELs 950. Beam shaping metasurfaces 970 may also provide different deflection angles for the emitted near-infrared light. In one implementation, the deflection angle of a given VCSEL is defined as the average emission angle of the emitted infrared beam relative to a vector normal to the substrate at the given VCSEL. For example, the deflection angle of beam 959C may be approximately zero where vector 957C (vector 957C being normal to the substrate 980 at VCSEL 950C) illustrates the average emission angle of beam 959C is approximately zero. The deflection angle of beam 959E illustrated by vector 957E may be 20 degrees tilted with respect to vector 957C. Or the deflection angle of beam 959E illustrated by vector 957E may be 20 degrees tilted with respect to a vector (not illustrated) that is normal to substrate 980 at the position of VCSEL 950E. These deflection angles may be different when substrate 980 is not planar, for example.

Near-eye optical element 990 shows that VCSELs 950 are disposed on substrate 980. In some embodiments, substrate 980 is an optically transparent substrate such as glass or plastic and incorporated into lens 921, for example. Near-eye optical element 990 illustrates a transparent encapsulation layer 988 that may be disposed between VCSELs 950, in some implementations.

Beam shaping metasurfaces 970 may include the characteristics of beam shaping profiles describe in connection to FIGS. 5A-8B to illuminate eye 902, for example. Beam shaping metasurfaces 970 may increase a deflection angle of the beam shaping metasurfaces as the beam shaping metasurfaces get closer to an outside boundary of the substrate. For example, the deflection angle associated with vector 957A of beam 959A may be larger than the deflection angle associated with vector 957B of beam 959B, which may be larger than the deflection angle associated with a vector 957C of beam 959C. And, the deflection angle associated with a vector 957E of beam 959E may be larger than the deflection angle associated with vector 957D of beam 959D, which may be larger than the deflection angle associated with vector 957C of beam 959C. The deflection angle of beam 959C may be approximately zero degrees.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HIVID) connected to a host computer system, a standalone HMD, a mobile device or computing system, or any other hardware platform capable of providing artificial reality content to one or more viewers.

The term “processing logic” in this disclosure may include one or more processors, microprocessors, multi-core processors, Application-specific integrated circuits (ASIC), and/or Field Programmable Gate Arrays (FPGAs) to execute operations disclosed herein. In some embodiments, memories (not illustrated) are integrated into the processing logic to store instructions to execute operations and/or store data. Processing logic may also include analog or digital circuitry to perform the operations in accordance with embodiments of the disclosure.

A “memory” or “memories” described in this disclosure may include one or more volatile or non-volatile memory architectures. The “memory” or “memories” may be removable and non-removable media implemented in any method or technology for storage of information such as computer-readable instructions, data structures, program modules, or other data. Example memory technologies may include RAM, ROM, EEPROM, flash memory, CD-ROM, digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device.

Communication channels may include or be routed through one or more wired or wireless communication utilizing IEEE 802.11 protocols, BlueTooth, SPI (Serial Peripheral Interface), I²C (Inter-Integrated Circuit), USB (Universal Serial Port), CAN (Controller Area Network), cellular data protocols (e.g. 3G, 4G, LTE, 5G), optical communication networks, Internet Service Providers (ISPs), a peer-to-peer network, a Local Area Network (LAN), a Wide Area Network (WAN), a public network (e.g. “the Internet”), a private network, a satellite network, or otherwise.

A computing device may include a desktop computer, a laptop computer, a tablet, a phablet, a smartphone, a feature phone, a server computer, or otherwise. A server computer may be located remotely in a data center or be stored locally.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

A tangible non-transitory machine-readable storage medium includes any mechanism that provides (i.e., stores) information in a form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A vertical-cavity surface-emitting laser (VCSEL) comprising:
a first reflector layer;
a second reflector layer;
a laser cavity disposed between the first reflector layer and the second reflector layer, wherein the laser cavity is configured to emit laser light; and
a metasurface configured to apply a beam shaping profile to the laser light to generate shaped laser light in response to receiving the laser light from the laser cavity.

2. The VCSEL of claim 1, wherein the metasurface is formed in a refractive semiconductor layer of the VCSEL.

3. The VCSEL of claim 1, wherein the metasurface includes a first refractive semiconductor layer and a second refractive semiconductor layer, wherein the first refractive semiconductor layer is disposed between the second refractive semiconductor layer and the second reflector layer.

4. The VCSEL of claim 3, wherein a first refractive index of the first refractive semiconductor layer is lower than a second refractive index of the second refractive semiconductor layer.

5. The VCSEL of claim 4, wherein the first refractive semiconductor layer has a thickness that is constant and the second refractive semiconductor layer includes nanostructures of the metasurface.

6. The VCSEL of claim 3, wherein a first refractive index of the first refractive semiconductor layer is higher than three at near-infrared wavelengths, and wherein a second refractive index of the second refractive semiconductor layer is higher than three at near-infrared wavelengths.

7. The VCSEL of claim 3, wherein the first refractive semiconductor layer includes indium-gallium-phosphate, and wherein the second refractive semiconductor layer includes gallium-arsenide or aluminum-gallium-arsenide.

8. The VCSEL of claim 1, wherein the metasurface is polarization insensitive.

9. The VCSEL of claim 1, wherein the beam shaping profile includes a meta-lens component to control a beam divergence of the shaped laser light, and wherein the beam shaping profile includes a meta-prism component to control a deflection angle of the shaped laser light.

10. The VCSEL of claim 1, wherein the metasurface is formed in a refractive dielectric layer of the VCSEL.

11. The VCSEL of claim 1, wherein the metasurface includes nanopillars having different sizes configured to shape the laser light into the shaped laser light.

12. The VCSEL of claim 11, wherein the nanopillars include first round nanopillars having a first radius, and wherein the nanopillars include second round nanopillars having a second radius that is different from the first radius.

13. A method of fabricating a light source, the method comprising:
fabricating a vertical-cavity surface-emitting laser (VCSEL) on a wafer, wherein the VCSEL is configured to emit laser light through an aperture of the VCSEL;
forming a refractive semiconductor layer over the aperture of the VCSEL while the VCSEL remains on the wafer; and
forming a metasurface in the refractive semiconductor layer, wherein the metasurface is formed in a subtractive process of the refractive semiconductor layer, and wherein the metasurface is configured to apply a beam shaping profile to the laser light to generate shaped laser light.

14. The method of claim 13, wherein the subtractive process includes etching nanostructures of the metasurface into the refractive semiconductor layer.

15. The method of claim 14 further comprising:
forming a refractive layer prior to forming the refractive semiconductor layer, wherein the refractive layer is formed between the VCSEL and the refractive semiconductor layer, and wherein the refractive layer functions as an etch stop for etching the nanostructures into the refractive semiconductor layer.

16. The method of claim 15, wherein a first refractive index of the refractive layer is lower than a second refractive index of the refractive semiconductor layer.

17. The method of claim 15, wherein the refractive semiconductor layer includes gallium-arsenide, and wherein the refractive layer includes indium-gallium-phosphate.

18. The method of claim 15, wherein the metasurface has a thickness of less than 500 nm.

19. A near-eye optical element comprising:
a refractive layer;
a first light source coupled with the refractive layer, the first light source comprising:
a first laser configured to emit first near-infrared laser light; and
a first metasurface configured to receive the first near-infrared laser light and apply a first beam shaping profile to the first near-infrared laser light to generate first shaped laser light to direct to an eyeward side of the near-eye optical element; and
a second light source coupled with the refractive layer, the second light source comprising:
a second laser configured to emit second near-infrared laser light; and
a second metasurface configured to receive the second near-infrared laser light and apply a second beam shaping profile to the second near-infrared laser light to generate second shaped laser light to direct to the eyeward side of the near-eye optical element, wherein the first beam shaping profile is different from the second beam shaping profile.

20. The near-eye optical element of claim 19, wherein the first metasurface is formed of a first refractive semiconductor layer integrated with the first laser, and wherein the second metasurface is formed of a second refractive semiconductor layer integrated with the second laser.
